(19) United States
(12) Patent Application Publication
(10) Pub. No.: US 2006/0028857 A1
(43) Pub. Date: Feb. 9, 2006

(54) Semiconductor memory device

(76) Inventor: Atsushi Sueoka, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/066,292

(22) Filed: Feb. 28, 2005

(30) Foreign Application Priority Data
Aug. 6, 2004 (JP) 2004-231166

(51) Int. Cl. G11C 11/24

(52) U.S. Cl. 365/149

(57) ABSTRACT

A semiconductor memory device includes a first memory cell array, a plurality of bit lines, a plurality of word lines and a plate potential generating circuit. In the first memory cell array, a plurality of memory cells are arranged in a matrix, and respectively include memory cell transistors and memory cell capacitors which include first and second electrodes. The bit lines are connected to the first electrodes by the memory cell transistors, and the word lines are connected to gate electrodes of the memory cell transistors. The plate potential generating circuit applies a predetermined potential to each of the second electrodes, and is located on a first line from which memory cells on the both sides of the first memory cell array in a first direction in which the word lines extend are substantially equidistant.

### CROSS-REFERENCE TO RELATED APPLICATIONS

This application is based upon and claims the benefit of priority from prior Japanese Patent Application No. 2004-231166, filed Aug. 6, 2004, the entire contents of which are incorporated herein by reference.

### BACKGROUND OF THE INVENTION

1. Field of the Invention

The present invention relates to a semiconductor memory device, and in particular a DRAM (Dynamic Random Access Memory).

2. Description of the Related Art

In general, a DRAM includes an array of memory cells as a memory cell array, each of which comprises a memory cell transistor and a memory cell capacitor. To one of electrodes of the memory cell capacitor, the memory cell transistor is connected, and to the other, a plate potential is applied.

Furthermore, the DRAM includes a plate potential generating circuit (VPL generating circuit). The plate potential generating circuit is connected to the memory cell capacitors in the memory cells by plate lines. The plate potential generating circuit generates a plate potential, and applies it to each of the memory cells (see Jpn. Pat. Appln. KOKAI Publication No. 8-250674).

### BRIEF SUMMARY OF THE INVENTION

A semiconductor memory device according to the first aspect of the present invention comprises: a first memory cell array in which a plurality of memory cells are arranged in a matrix, the memory cells including memory cell transistors and memory cell capacitors, respectively, the memory cell capacitors including first electrodes and second electrodes, respectively; a plurality of bit lines connected to the first electrodes by the memory cell transistors; a plurality of word lines connected to gate electrodes of the memory cell transistors; and a first plate potential generating circuit which applies a predetermined potential to the second electrodes. The first plate potential generating circuit is provided on a first line from which memory cells located on the both sides of the first memory cell array in a first direction in which the word lines extend are substantially equidistant.

A semiconductor memory device according to the second aspect of the present invention comprises: a first memory cell array in which a plurality of memory cells are arranged in a matrix, the memory cells including memory cell transistors and memory cell capacitors, respectively, the memory cell capacitors including first electrodes and second electrodes, respectively; a plurality of bit lines connected to the first electrodes by the memory cell transistors; a plurality of word lines connected to gate electrodes of the memory cell transistors; and a first plate potential generating circuit which applies a predetermined potential to the second electrodes. The first plate potential generating circuit is provided on a second line from which memory cells located on the both sides of the first memory cell array in a second direction in which the bit lines extend are substantially equidistant.

### BRIEF DESCRIPTION OF THE SEVERAL VIEWS OF THE DRAWING

FIG. 1 is a schematic view of a DRAM according to the first embodiment of the present invention.

FIG. 2 is a circuit diagram of a main portion of a memory cell array CA0 shown in FIG. 1.

FIG. 3 is a circuit diagram showing the structure of a VPL generating circuit 1 shown in FIG. 1.

FIG. 4 is a schematic view of a DRAM according to the second embodiment of the present invention.

FIG. 5 is a schematic view of a DRAM according to the third embodiment of the present invention.

FIG. 6 is a schematic view of a DRAM according to the fourth embodiment of the present invention.

FIG. 7 is a schematic view of a DRAM according to the fifth embodiment of the present invention.

FIG. 8 is a schematic view of a DRAM according to the sixth embodiment of the present invention.

FIG. 9 is a schematic view of a DRAM according to the seventh embodiment of the present invention.

FIG. 10 is a plan view of a memory cell array CA7 shown in FIG. 9.

FIG. 11 is a plan view of part of the memory cell array CA7 shown in FIG. 10, which corresponds to I/O0.

FIG. 12 is a cross section taken along line XII-XII in FIG. 11.

FIG. 13 is a schematic view of a DRAM according to the eighth embodiment of the present invention.

FIG. 14 is a plan view of part of a memory cell array CA7 shown in FIG. 13, which corresponds to I/O0.

FIG. 15 is a cross section taken along line XII-XII in FIG. 14.

FIG. 16 is a schematic view of an embodiment of a DRAM.

FIG. 17 is a schematic view showing the structure of a memory cell array CA0 shown in FIG. 16.

FIG. 18 is a circuit diagram of a main portion of the memory cell array CA0.

### DETAILED DESCRIPTION OF THE INVENTION

The inventors of the present invention have developed a DRAM having the following structure:

FIG. 16 is a schematic view showing an embodiment of the DRAM. The DRAM includes fourth memory cell arrays CA0 to CA3. In each of these memory cell arrays, a plurality of memory cells MC are arranged in a matrix.

The DRAM is provided with a VPL generating circuit (VPL Gen.) 1. The VPL generating circuit 1 generates a plate potential VPL. The VPL generating circuit 1 applies the plate potential VPL to each of the memory cells MC. The plate potential VPL is set at, for example, 0.5 VBLH which is half a high-level bit line potential VBLH. The VPL generating circuit 1 is located close to a left corner of the memory cell array CA3.

FIG. 17 is a schematic view showing the structure of the memory cell array CA0 shown in FIG. 16. It should be noted that the structures of the memory cell arrays CA1 to CA3 are the same as that of the memory cell array CA0.

In the memory cell array CA0, an m number of pairs of bit lines BL0 and /BL0 to BLm-1 and /BLm-1 and an n number of word lines WL0 to WLn-1 are provided. To the pairs of bit lines BL0 and /BL0 to BLm-1 and /BLm-1, peripheral circuits such as sense amplifiers SA are connected. At the intersections of those bit lines and word lines, memory cells MC (not shown) are provided.

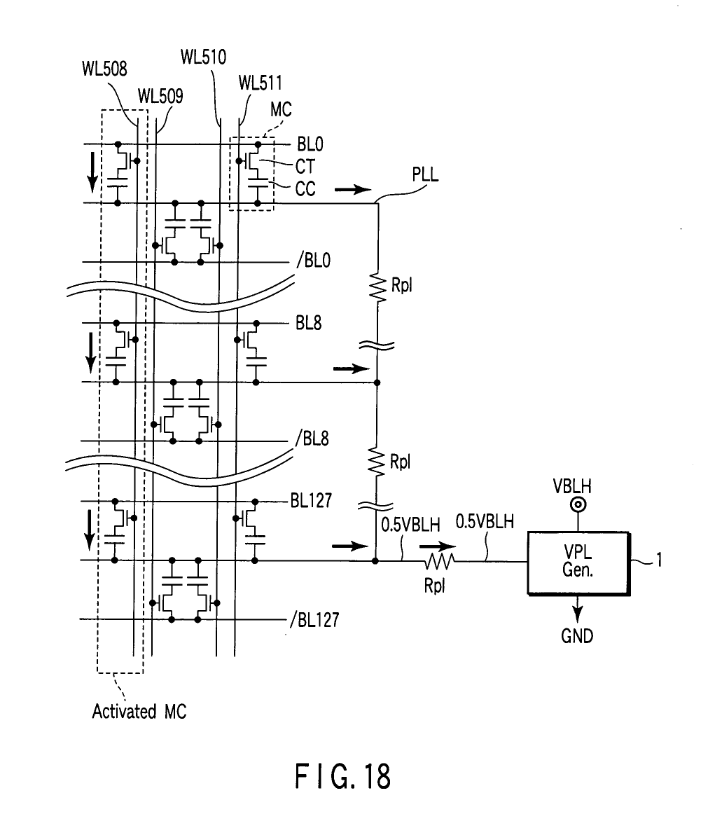

FIG. 18 is a circuit diagram of a main portion of the memory cell array CA0. To be more specific, FIG. 18 shows a DRAM which includes 128 pairs of bit lines and 512 word lines, by way of example.

Each of the memory cells MC comprises a memory cell transistor CT and a memory cell capacitor CC. To be more specific, in the memory cell MC shown in FIG. 18, one of the electrodes of the memory cell capacitor CC is connected to a plate line PLL, and the other is connected to a bit line BL0 by a memory cell transistor CT. The memory cell transistor CT includes a gate electrode connected to the word line WL 511. The same is true of the other memory cells MC. The plate line PLL is connected to the VPL generating circuit 1.

With respect to the DRAM having the above structure, it will be explained how data is written into a memory cell MC. The following explanation will refers to the case where data is written into the memory cell MC shown in FIG. 18. When data is written to the memory cell MC, the memory cell capacitor CC thereof is charged or discharged.

In the case where the memory cell capacitor CC be charged, for example, when a word line WL 508 is activated, current flows in a direction indicated by arrows in FIG. 18. To be more specific, at the time of charging the memory cell capacitor CC, current flows from the high-level bit line voltage VBLH (applied to a sense amplifier) to the memory cell capacitor CC, the VPL generating circuit 1 and the ground GND (applied to the VPL generating circuit 1) in this order.

On the other hand, at the time of discharging the memory cell capacitor CC, current flows from the high-level bit line voltage VBLH (applied to the VPL generating circuit 1) to the VPL generating circuit 1, the memory cell capacitor CC, and the ground GND (applied to the sense amplifier) in this order. The current flowing from the VPL generating circuit 1 will be referred to as plate current.

In recent years, it has been required to increase the bandwidth of a DRAM, and the number of bits of data which is read or written at a time (which will be hereinafter referred to as the number of data inputs/outputs) has been increased to satisfy such a requirement. In general, for example, if a cell array is provided to have 512 rows, 1K columns and a capacity of 512 K bits, it is formed to have 512 rows, 64 columns and 16 I/Os. It should be noted that the above rows and columns correspond to row addresses and column addresses, respectively, and the I/Os corresponds to the data inputs/outputs.

In order to increase the above bandwidth, the cell array is formed to increase the I/Os (i.e., the data inputs/outputs). For example, it is formed to have 512 rows, 8 columns and 128 I/Os. In the cell array, the number of memory cells MC which can be subjected to reading/writing at a time is increased, and the bandwidth is thus increased.

Furthermore, the frequency of access to memory cells per unit time (i.e., clock frequency), as well as the number of I/Os, has been gradually increased, in order to increase the bandwidth.

When the bandwidth is increased, the amount of plate current at the time of wiring data (which will be hereinafter referred to as the writing time) is increased. The amount of plate current at the writing time, which is denoted by “IPLwrite”, is expressed by the following equation:
IPLwrite=(the number of I/Os·Cs·VBLH)/tCK
where Cs is the capacity of a memory cell capacitor, and tCK is a cycle time.

As can be seen from the above equation, when the bandwidth is increased, the number of I/Os, i.e., that of memory cells MC, which are accessed in one cycle, is increased, and the cycle time tCK is shortened, as a result of which the amount of plate current at the writing time is increased.

Wiring resistors Rpl are provided in plate lines PLL connecting the VPL generating circuit 1 and the memory cell capacitors CC. Thus, the potential generated from the VPL generating circuit 1 is varied by the wiring resistors Rpl. That is, even when the potential needs to be maintained, i.e., it is 0.5 VBLH, potential variation ΔVPL is made to occur by the wiring resistors Rpl in the plate line PLL, to satisfy the following equation: ΔVPL=IPL·Rpl.

That is, at the time of discharging the memory cell capacitor CC, the plate current flows from the memory cell capacitor CC toward the VPL generating circuit 1, as a result of which the plate potential is lowered from 0.5 VPLH by the wiring resistors Rpl. On the other hand, at the time of charging the memory cell capacitor CC, the plate current flows from the VPL generating circuit 1 toward the memory cell capacitor CC, as a result of which the plate potential is raised from 0.5 VBLH by the wiring resistors Rpl.

The above potential variation reduces the amount of charges moved into memory cell MC during writing. For example, suppose zeroes (data “0”) are written into the memory cells MC in advance, and ones (data “1”) are written into every 128 memory cells MC of the memory cells MC every cycle, i.e., writing is performed in units of 128 memory cells MC. In this case, the plate potentials of the memory cells MC rewritten to in the present cycle are higher than those of the memory cells MC written to in the previous cycle. If the plate potentials of memory cells MC are changed to back to a predetermined potential at the time of reading data (which will be hereinafter referred to as the reading time), the plate potentials at the writing time are different from those at the reading time.

When the plate potentials obtained at the writing time are different from those at the reading time, a voltage applied as a signal transmitted from memory cells MC to bit lines varies. In a 0.5-VBLH pre-charge method (in which bit lines are pre-charged to have a potential of 0.5 VBLH), when the difference between the plate potentials at the writing time and those at the reading time is ΔVPL, a voltage “Vsig” applied as the above signal at the reading time is expressed by the following equation:
Vsig=((Vsn+ΔVPL)−0.5 VBLH)×(1/(1+Cb/Cs))
where Vsn is the potential of a memory cell capacitor (written with charges of Cs (Vsn−VPL+ΔVPL)), and Cs is the capacity of bit lines.

As can be seen from this equation, a voltage applied as a signal to the bit lines varies by approximately “ΔVPL×(1/(1+Cb/Cs))”. If data stored in memory cells MC (which will be hereinafter referred to as memory cell data) is “0”, when the plate potentials thereof are more raised at the reading time than at the writing time (ΔVPL>0), the voltage applied as the signal is decreased. If the memory cell data is “1”, when the plate potentials thereof are more fallen at the reading time than at the writing time (ΔVPL<0), the voltage applied as the signal is decreased. To summarize, the voltage is decreased under the following condition:

When the memory cell data is “0”, VPLwrite<VPLread, and when the memory cell data is “1”, VPLwrite>VPLread, where VPLwrite is the plate potential at the writing time, and VPLread is that at the reading time.

As described above, wiring resistors Rpl of plate lines PLL also cause variation of the plate potentials. That is, their presence is one of the factors in variation of the plate potentials. The resistance value of wiring resistors Rpl of a plate line PLL is proportional to the distance between the VPL generating circuit 1 and a memory cell MC to which a potential from the VPL generating circuit 1 is applied. Where Length_BL is the length of each of the memory cell arrays in the extending direction of the bit lines, and Length_WL is the length of each of the memory cell arrays in the extending direction of the word lines, in the DRAM shown in FIG. 16, the distance between the VPL generating circuit 1 and one of the memory cells MC which is located furthest from the VPL generating circuit 1 is approximately “Length WL+4·Length BL”, and the resistance value of the wiring resistor Rpl is determined by multiplexing the above distance by a resistance value per unit length.

Of the memory cells MC, the memory cell furthest from the VPL generating circuit 1 is influenced most by variation of the plate potential during writing, which is due to wiring resistors Rpl. Thus, a voltage applied as a signal transmitted from the above furthest memory cell or peripheral memory cells is reduced, as a result of which data cannot be accurately read.

The plate current tends to be increased as the bandwidth is increased. This influence on the DRAM is not ignorable.

The embodiments of the present invention which has been made in consideration of the above circumstances will be explained with reference to the accompanying drawings. In the following explanations, elements having the same functions and the same structures will be denoted by the same reference numerals. After they are each explained one time, their explanations will not be repeated, except as need arises.

### First Embodiment

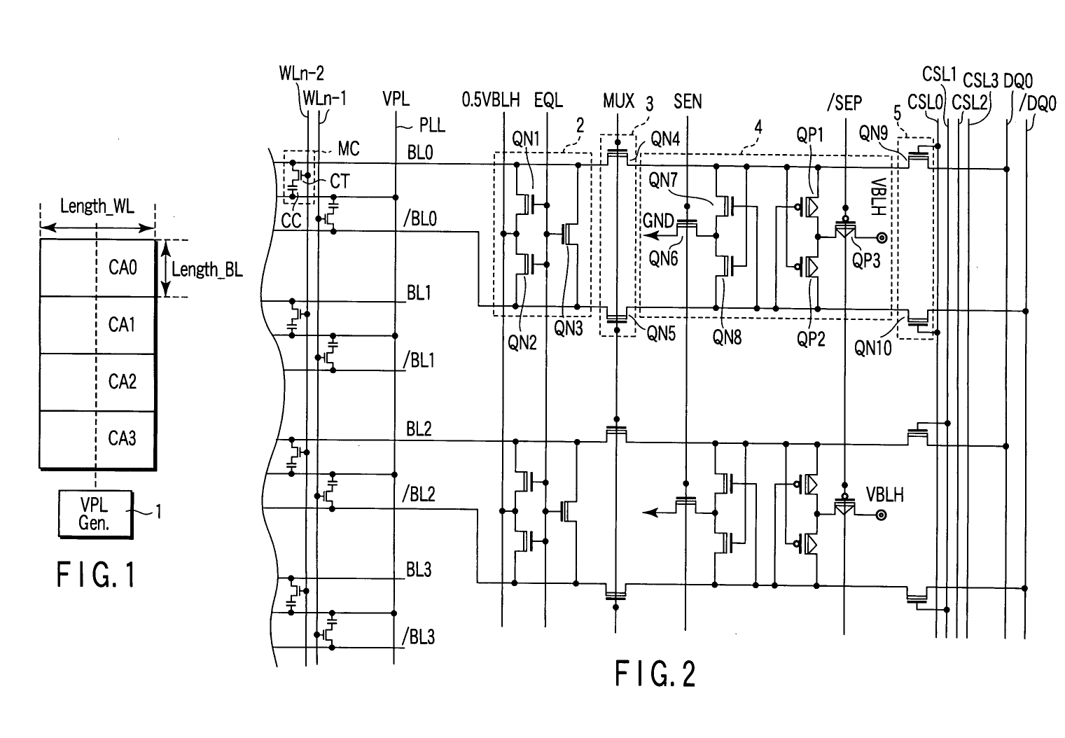

FIG. 1 is a schematic view of a DRAM according to the first embodiment of the present invention. The DRAM comprises four memory cell arrays (memory cell array portions) CA0 to CA3. In each of the memory cell arrays CA0 to CA3, a number of memory cells MC are arranged in a matrix. The memory cell arrays CA0 to CA3 are arranged in the extending direction of bit lines.

Each of the memory cell arrays CA0 to CA3 has a capacity of 512 K bits. Thus, the DRAM shown in FIG. 1 has a capacity of 2 M bits. Also, the DRAM includes a VPL generating circuit (VPL Gen.) 1, which applies a plate potential VPL to each of the memory cells MC.

The memory cell array CA0 includes, e.g., 1024 bit lines BL (i.e., 512 pairs of bit lines BL and /BL) and 512 word lines WL. To the pairs of bit lines BL and /BL, peripheral circuits such as sense amplifiers (SA) are connected. At the intersections of the bit lines BL and the word lines WL, memory cells MC not shown are provided. The memory cell arrays CA1 to CA3 have the same structure as the memory cell array CA0.

Next, the peripheral circuits connected to the bit lines will be explained. FIG. 2 is a circuit diagram of a main portion of the memory cell array CA0 shown in FIG. 1. As shown in FIG. 2, to a pair of bit lines BL0 and /BL0, an equalizing circuit 2, a cell array selecting circuit 3, a sense amplifier circuit 4 and a column gate 5 are connected.

The equalizing circuit 2 comprises three N-type MOS transistors QN1 to QN3. To the equalizing circuit 2, a potential of 0.5 VBLH and an equalizing signal EQL are supplied from a control signal generating circuit not shown. To be more specific, the equalizing signal EQL is supplied to gate electrodes of the three N-type MOS transistors QN1 to QN3. It should be noted that “VBLH” denotes a high level bit line potential. When the signal EQL is activated, the equalizing signal 2 equalizes the potentials of the bit lines BL0 and /BL0 such that they are set to, e.g., 0.5 VBLH.

The cell array selecting circuit 3 comprises two N-type MOS transistors QN4 and QN5. To the cell array selecting circuit 3, an array selecting signal MUX is supplied. To be more specific, the array selecting signal MUX is supplied to gate electrodes of the two N-type MOS transistors QN4 and QN5. The cell array selecting circuit 3 selects the memory cell array CA0 when the signal MUX is activated.

The sense amplifier circuit 4 comprises an N-type MOS sense amplifier in which two N-type MOS transistor QN7 and QN8 are cross-coupled with each other and a P-type MOS sense amplifier in which two PMOS transistors QP1 and QP2 are cross-coupled with each other. To the N-type MOS sense amplifier, a ground potential GND is applied through an N-type MOS transistor QN6.

To the PMOS sense amplifier, the high level bit line potential VBLH is applied through a P-type MOS transistor QP3. To the sense amplifier circuit 4, signals SEN and /SEP are input. When the signal SEN is activated, the ground potential GND is applied to the N-type MOS sense amplifier. Also, when the signal /SEP is activated, the potential VBLH is applied to the P-type MOS sense amplifier. The sense amplifier 4 having the above structure amplifies data read out through the bit lines BL0 and /BL.

The column gate 5 comprises two N-type MOS transistors QN9 and QN10. To the column gate 5, a column selecting signal CSL0 is supplied. To be more specific, a column selecting signal CSL0 is supplied to gate electrodes of the two N-type MOS transistors QN9 and QN10.

When the column selecting signal CSL0 is activated, the column gate 5 transfers data of the pair of bit lines BL0 and /BL0 to a pair of data lines DQ0 and /DQ0 or data of the data lines DQ0 and /DQ0 to the pair of bit lines BL0 and /BL0. The same is true of other pairs of bit lines.

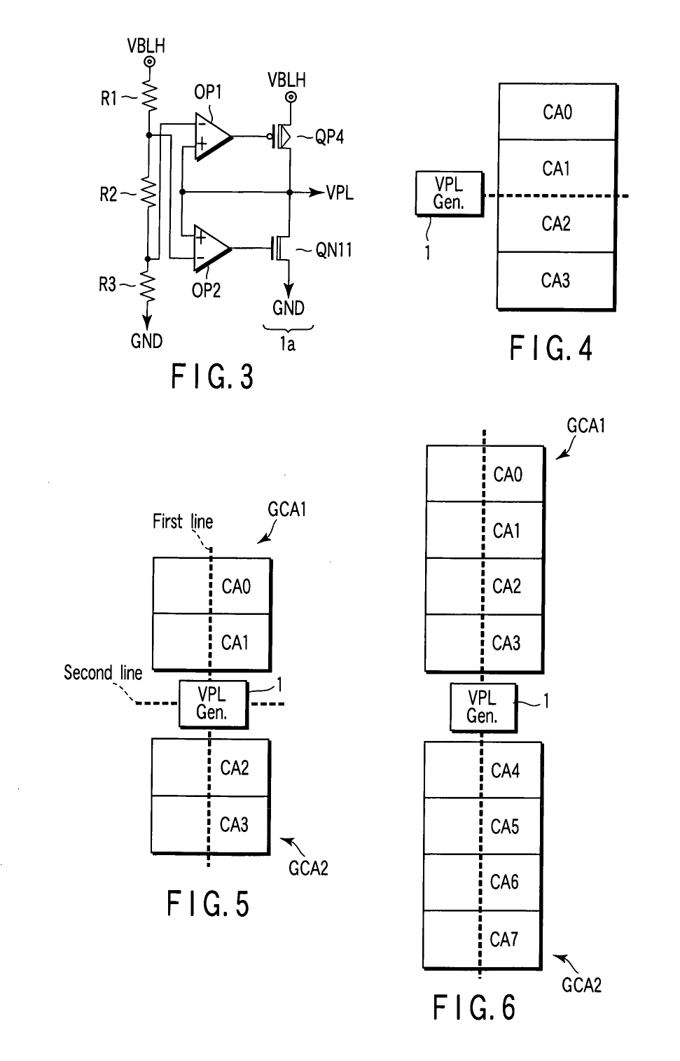

Next, the structure of the VPL generating circuit 1 will be explained. FIG. 3 is a circuit diagram showing the structure of the VPL generating circuit 1 shown in FIG. 1. The VPL generating circuit 1 comprises three resistors R1 to R3, two differential amplifying circuits OP1 and OP2, a P-type MOS transistor QP4 and an N-type MOS transistor QN11. The tree resistors R1 to R3 are connected in series, and the voltage between the potential VBLH and the ground potential GND is subjected to voltage division by the resistors R1 to R3.

An output circuit 1a comprises the transistor QP4 and the transistor QN11. The node between the resistors R2 and R3 is connected to an inversion input terminal of the differential amplifying circuit OP1, and the output node of the output circuit 1a is connected to a non-inversion input terminal of the differential amplifying circuit OP 1. The output terminal of the differential amplifying circuit OP1 is connected to the gate electrode of the transistor QP4. The differential amplifying circuit OP1 turns on the transistor QP4 to raise the potential of the output node of the output circuit 1a, when the potential of the output node of the output circuit 1a becomes lower than that of the node between the resistors R2 and R3.

On the other hand, the node between the resistors R1 and R2 is connected to an inversion input terminal of the differential amplifying circuit OP2, and the output node of the output circuit 1a is connected to a non-inversion input terminal of the differential amplifying circuit OP2. The output terminal of the differential amplifying circuit OP2 is connected to the gate electrode of the transistor QN11. The differential amplifying circuit OP2 turns on the transistor QN11 to lower the output node of the output circuit 1a, when the potential of the output node of the output circuit 1a becomes higher than that of the node between the resistors R1 and R2. Due to the above controls of the differential amplifying circuits OP1 and OP2, the VPL generating circuit 1 can generate and output a desired plate potential VPL.

In the DRAM having the above structure, the VPL generating circuit 1 is located on a line (the broken line in FIG. 1) which bisects the memory cell arrays, for example, CA0, in the extending direction of the word lines, such that the memory cells MC on each sides of the memory cell arrays in the extending direction of the word lines are substantially equidistant from the line. Alternatively, the VPL generating circuit 1 is located on a line from which two bit lines on each side of the memory cell arrays in the extending direction of the word lines are substantially equidistant. To be more specific, the VPL generating circuit 1 is provided such that the output circuit 1a of the VPL generating circuit 1 is located on the above line.

By virtue of the above structural feature, the distance between the VPL generating circuit 1 and one of the memory cells MC which is located furthest from the VPL generating circuit 1 substantially corresponds to “(Length_WL/2)+4 Length_BL”. Thereby, the distance is smaller than that of the DRAM shown in FIG. 16 by approximately “Length_WL/2”.

As explained above in detail, in the first embodiment, the VPL generating circuit 1 for generating a plate potential to be applied to a memory cell capacitor CC is provided on a line from which memory cells MC on the both sides of each of the memory cell arrays are separated by substantially the same distance in the extending direction of the word lines.

Therefore, according to the first embodiment, variation of the plate potential at the writing time can be suppressed, since the wiring resistance of the plate lines can be reduced. Thus, reduction of a voltage applied as a signal transmitted from a memory cell MC to a bit line can be prevented, as a result of which data can be read out with a high precision.

### Second Embodiment

FIG. 4 is a schematic view of a DRAM according to the second embodiment of the present invention. The DRAM comprises four memory cell arrays CA0 to CA3 as a memory cell array group, which are arranged in the extending direction of the bit lines.

In the DRAM according to the second embodiment, the VPL generating circuit 1 is located on a line which bisects the memory cell array group (i.e., the memory cell arrays CA0 to CA3) in the extending direction of the bit lines, such that the memory cells MC on the both end sides of the memory cell array group in the extending direction of the bit lines are substantially equidistant from the line. Alternatively, the VPL generating circuit 1 is located on a line from which the word lines on the both end sides of the memory cell array group in the extending direction of the bit lines are substantially equidistant.

By virtue of the above structural feature, the distance between the VPL generating circuit 1 and one of the memory cells MC which is located furthest from the VPL generating circuit 1 substantially corresponds to “Length_WL+2·Length_BL”. Thereby, the distance is smaller than that in the DRAM shown in FIG. 16 by approximately “2 Length_BL”.

Therefore, according to the second embodiment, variation of the plate potential at the writing time can be suppressed, since the wiring resistance of the plate lines can be reduced. Thus, reduction of a voltage applied as a signal transmitted from a memory cell MC to a bit line can be prevented, as a result of which data can be read out with a high precision.

The memory cell arrays is not limitative in number.

### Third Embodiment

FIG. 5 is a schematic view of a DRAM according to the third embodiment of the present invention. The DRAM includes two memory cell array groups GCA1 and GCA2. The memory cell array group GCA1 consists of two memory cell arrays CA0 and CA1. The memory cell array group GCA2 consists of two memory cell arrays CA2 and CA3. The two memory cell array groups GCA1 and GCA2 are arranged in the extending direction of the bit lines.

Furthermore, in the DRAM according to the third embodiment, the VPL generating circuit 1 is located at the intersection of a first line and a second line. The first line is a line from which the memory cells MC on each side of the memory cell arrays, e.g., CA0, in the extending direction of the word lines, are substantially equidistant. The second line is a line from which the memory cells MC on outer peripheral sides of the memory cell array groups GCA1 and GCA2 in the extending direction of the bit lines are substantially equidistant. In this case, the above outer peripheral sides of the memory cell array groups GCA1 and GCA2 means sides which are respectively located opposite to inner peripheral sides of the memory cell array groups GCA1 and GCA2 which are close to the VPL generating circuit 1.

Alternatively, the VPL generating circuit 1 is located at the intersection of a first line and a second line. The first line is a line from which the bit lines on each side of the memory cell arrays, e.g., CA0, in the extending direction of the word lines, are substantially equidistant. The second line is a line from which the word lines on outer peripheral sides of the memory cell array groups GCA1 and GCA2 in the extending direction of the bit lines are substantially equidistant.

By virtue of the above structural feature, the distance between the VPL generating circuit 1 and one of the memory cells MC which is located furthest from the VPL generating circuit 1 substantially corresponds to “(Length_WL/2)+2·Length_BL”. Thereby, the distance is smaller than that of the DRAM shown in FIG. 16 by approximately “(Length_WL/2)+2·Length BL”.

Therefore, according to the third embodiment, variation of the plate potential at the writing time can be suppressed, since the wiring resistance of the plate lines can be reduced. Thus, reduction of a voltage applied as a signal transmitted from a memory cell MC to a bit line can be prevented, as a result of which data can be read out with a high precision.

In addition, according to the third embodiment, the wiring resistance of the plate lines can be more greatly reduced than in the first and second embodiments.

The memory cell arrays which is included in the memory cell array group is not limitative in number.

### Fourth Embodiment

FIG. 6 is a schematic view of a DRAM according to the fourth embodiment of the present invention. The DRAM includes two memory cell array groups GCA1 and GCA2. The memory cell array group GCA1 consists of four memory cell arrays CA0 to CA3. The memory cell array group GCA2 consists of four memory cell arrays CA4 to CA7. The two memory cell array groups GCA1 and GCA2 are arranged adjacent to each other in the extending direction of the bit lines. Each of the above memory cell arrays has a capacity of 512 K bits. Therefore, the DRAM shown in FIG. 6 corresponds to a capacity of 4 M bits.

Furthermore, in the DRAM according to the fourth embodiment, the VPL generating circuit 1 is located on a line from which memory cells MC located on each side of the memory cell arrays in the extending direction of the word lines are substantially equidistant, and is also located between the two memory cell array groups GCA1 and GCA2.

By virtue of the above structural feature, in the fourth embodiment, the wiring resistance of the plate lines can be reduced as in the first embodiment, and the capacity of the memory is double that of the memory in the first embodiment. Thus, if the first embodiment is modified as in the fourth embodiment, the capacity of the memory in the first embodiment can be further increased.

The memory cell arrays which is included in the memory cell array group is not limitative in number.

### Fifth Embodiment

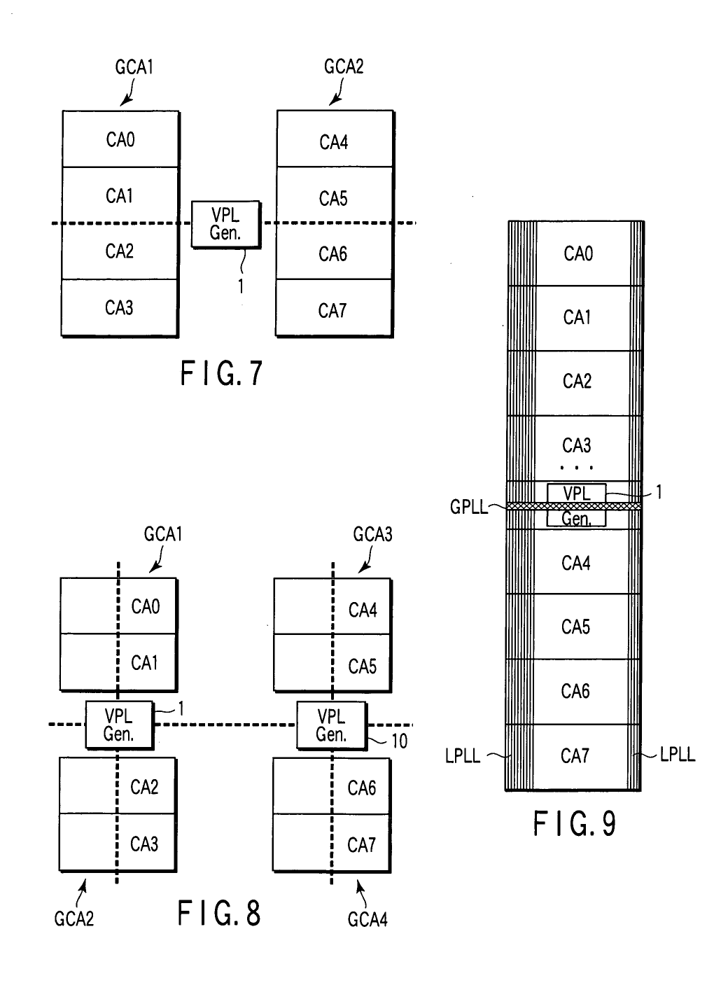

FIG. 7 is a schematic view of a DRAM according to the fifth embodiment of the present invention. The DRAM includes two memory cell array groups GCA1 and GCA2. The memory cell array group GCA1 consists of four memory cell arrays CA0 to CA3. The memory cell array group GCA2 consists of four memory cell arrays CA4 to CA7. The two memory cell array groups GCA1 and GCA2 are arranged adjacent to each other in the extending direction of the word lines.

Furthermore, in the DRAM according to the fifth embodiment, the VPL generating circuit 1 is located on a line from which memory cells MC on the both sides of the memory cell array group GCA1 (i.e., on outer peripheral sides of the memory cell arrays CA0 and CA3) in the extending direction of the bit lines are substantially equidistant, and is also located between the memory cell array groups GCA1 and GCA2.

By virtue of the above structural feature, in the fifth embodiment, the wiring resistance of the plate lines can be reduced as in the second embodiment, and the capacity of the memory is double that of the memory in the second embodiment. Thus, if the second embodiment is modified as in the fifth embodiment, the capacity of the memory in the second embodiment can be further increased.

The memory cell arrays which is included in the memory cell array group is not limitative in number.

### Sixth Embodiment

FIG. 8 is a schematic view of a DRAM according to the sixth embodiment of the present invention. The DRAM includes four memory cell array groups GCA1 to GCA4. The memory cell array group GCA1 consists of two memory cell arrays CA0 and CA1. The memory cell array group GCA2 consists of two memory cell arrays CA2 and CA3. The memory cell array group GCA3 consists of two memory cell arrays CA4 and CA5. The memory cell array group GCA4 consists of two memory cell arrays CA6 and CA7.

Furthermore, the DRAM according to the fifth embodiment includes two VPL generating circuits 1 and 10, which have the same structure.

The VPL generating circuit 1 is located on a line from which the memory cells MC on each side of the memory cell arrays CA0 to CA3 in the extending direction of the word lines are substantially equidistant, and is also located between the memory cell array groups GCA1 and GCA2.

The VPL generating circuit 10 is located on a line from which the memory cells MC on each side of the memory cell arrays CA4 to CA7 in the extending direction of the word lines are substantially equidistant, and is also located between the memory cell array groups GCA3 and GCA4.

By virtue of the above structural feature, in the sixth embodiment, the wiring resistance of the plate lines can be reduced as in the third embodiment, and the capacity of the memory is double that of the memory in the third embodiment. Thus, if the third embodiment is modified as in the sixth embodiment, the capacity of the memory in the third embodiment can be further increased.

The memory cell arrays which is included in the memory cell array group is not limitative in number.

### Seventh Embodiment

The seventh embodiment is provided as an example of a wiring structure of a DRAM. The seventh embodiment will be explained by referring to the case where the DRAM (shown in FIG. 6) according to the fourth embodiment is used in the seventh embodiment.

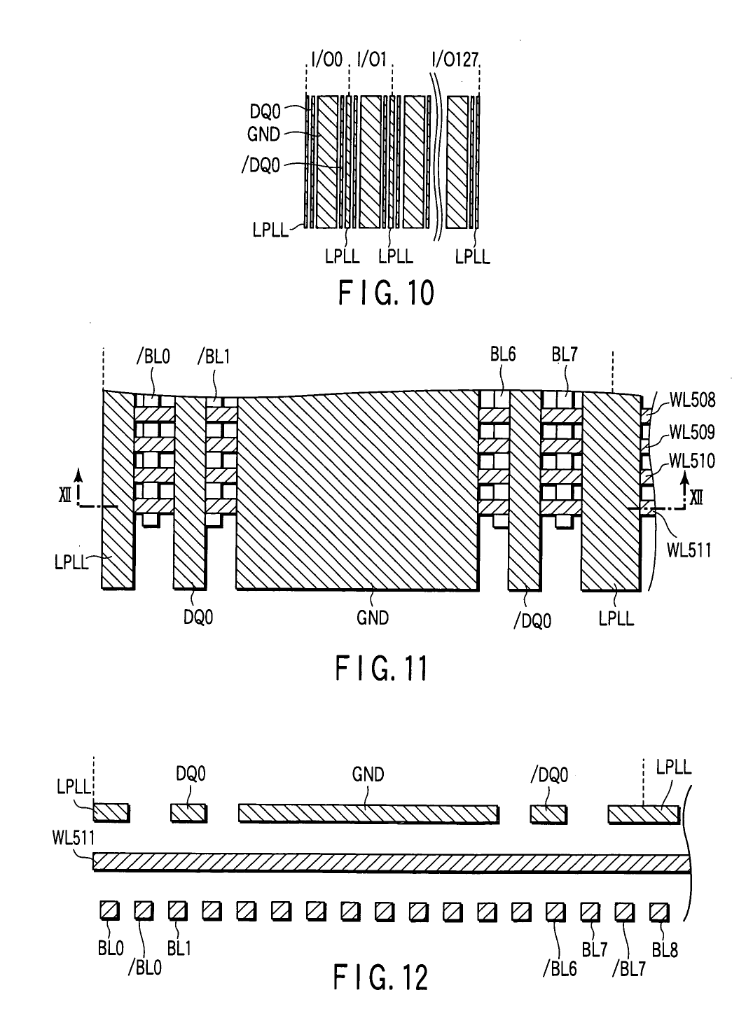

FIG. 9 is a schematic view of a DRAM according to the seventh embodiment of the present invention. The DRAM includes 128 I/Os. Each of the memory cell arrays includes, e.g., 1024 bit lines BL (i.e., 512 pairs of bit lines BL and /BL) and 512 word lines WL. Therefore, the DRAM is formed such that one group of eight bit lines BL is associated with one I/O. That is, the number of I/Os is equal to the number of groups of bit lines BL.

In each of the memory cell arrays (memory cell array portions) CA0 to CA7, local plate lines LPLL are provided to extend in the same direction as the bit lines. In an area in which the VPL generating circuit 1 is provided (i.e., between the memory cell arrays CA3 and CA4), a global plate line GPLL is provided to extend in the same direction as the word lines. The global plate line GPLL connects the local plate lines LPLL and the VPL generating circuit 1.

The plate lines PLL include the global plate line GPLL and the local plate lines LPLL. That is, the local plate lines LPLL are connected to the memory cell capacitors CC of the memory cell MC.

FIG. 10 is a plan view of the memory cell array CA7 shown in FIG. 9. It should be noted that the memory cell arrays CA0 to CA6 have the same structure as the memory cell array CA7.

In the memory cell array CA7, the local plate lines LPLL are arranged at a constant pitch (equivalent to a length over which one group of eight bit lines associated with one I/O are provided). In such a manner, the local bit lines LPLL are provided between the I/Os, as a result of which they can be provided within the range in which the I/Os are provided, i.e., without increasing the range in the extending direction of the word lines.

FIG. 11 is a plan view of part of the memory cell array CA7 shown in FIG. 10, which corresponds to I/O0. FIG. 12 is a cross section taken along line XII-XII in FIG. 11. In FIGS. 11 and 12, illustrations of layers located under a layer where the bit lines are provided will be omitted.

In a first metal layer, bit lines are provided. In a second metal layer, word lines are provided. In a third metal layer, data lines DQ, local plate lines LPLL and ground lines GND are provided. To be more specific, two data lines DQ and /DQ are respectively provided one group of eight bit lines BL and one group of eight bit lines /BL. For example, data lines DQ0 and /DQ0 are respectively provided for a group of eight bit lines BL0 to BL7 and a group of eight bit lines /BL0 to /BL7.

In the DRAM having the above structure, 129 local bit lines LPLL are provided without the need to increase the width of the DRAM in the extending direction of the word lines. The width of one local plate line LPLL is small. However, in the seventh embodiment, 129 local plate lines LPLL are provided. Their provision is equivalent to provision of a single wiring the width of which is 129 times greater than the width of one local plate line LPLL. Thereby, the wiring resistance of the plate lines PLL extending in the same direction as the bit lines (i.e., the wiring resistance of the local plate lines LPLL) can be reduced.

### Eighth Embodiment

The eighth embodiment is another example of the seventh embodiment.

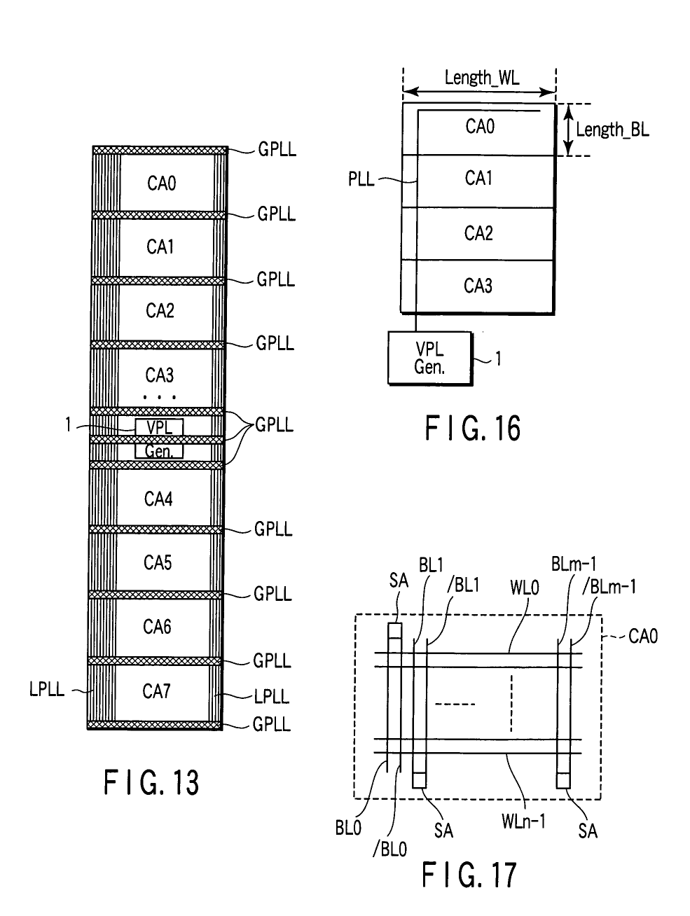

FIG. 13 is a schematic view of a DRAM according to the eighth embodiment of the present invention. The DRAM shown in FIG. 13 comprises global plate lines GPLL by which the memory cell arrays are separated from each other, in addition to global plate lines GPLL directly connected to the VPL generating circuit 1. Each of the global plate lines GPLL is connected to the above 129 local plate lines LPLL.

The plate lines PLL include the global plate lines GPLL and the local plate lines LPLL. That is, the local plate lines LPLL are connected to the memory cell capacitors CC of the memory cell MC.

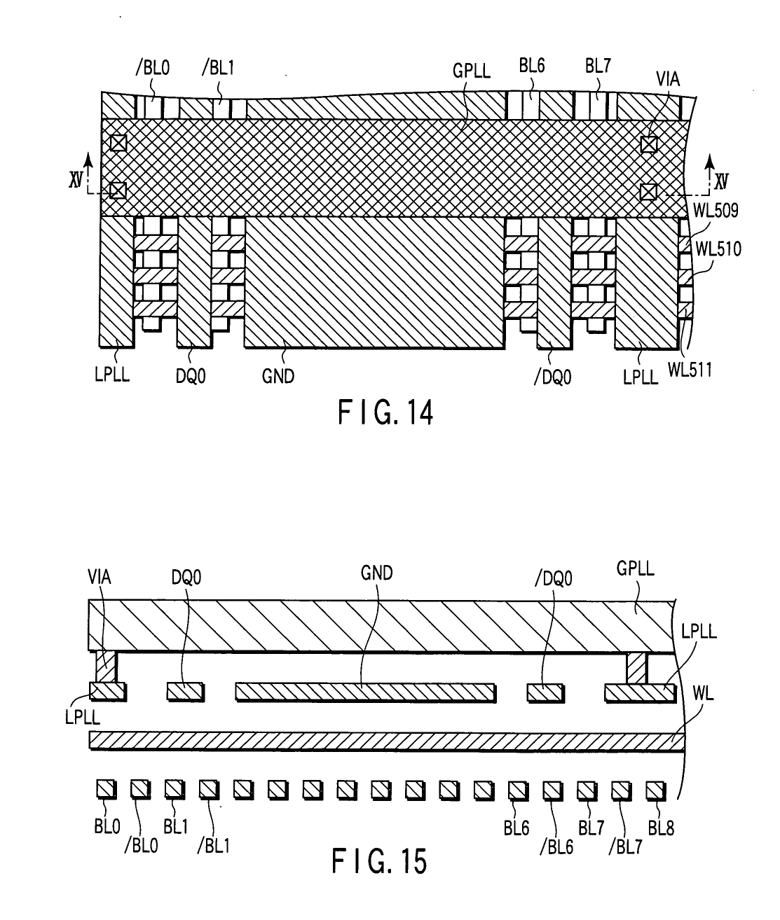

FIG. 14 is a plan view of part of a memory cell array CA7 shown in FIG. 13, which corresponds to I/O0. FIG. 15 is a cross section taken along line XV-XV in FIG. 14. In FIGS. 14 and 15, illustrations of layers located under a layer where the bit lines are provided will be omitted.

In a first metal layer, bit lines are provided. In a second metal layer, word lines are provided. In a third metal layer, data lines DQ, local plate lines LPLL and ground lines GND are provided.

In a fourth metal layer, global metal plates GPLL are provided. The global metal plates GPLL and the local plate lines LPLL are connected together by via plugs VIA.

In the DRAM having the above structure, the wiring resistance of the plate lines PLL in the extending direction of the word lines can be lowered. Furthermore, since, as stated above, a number of global plate lines GPLL are provided, the wiring resistance of the plate lines PLL in the extending direction of the word lines can be lowered without the need to increase the width of the global plate lines GPLL directly connected to the VPL generating circuit 1.

Furthermore, the global plate lines GPLL can be provided without the need to increase the width of the DRAM in the extending direction of the bit lines, since they are provided at the ends of the memory cell arrays.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a first memory cell array in which a plurality of memory cells are arranged in a matrix, the memory cells including memory cell transistors and memory cell capacitors, respectively, the memory cell capacitors including first electrodes and second electrodes, respectively;
a plurality of bit lines connected to the first electrodes by the memory cell transistors;
a plurality of word lines connected to gate electrodes of the memory cell transistors; and
a first plate potential generating circuit which applies a predetermined potential to the second electrodes,
wherein the first plate potential generating circuit is provided on a first line from which memory cells located on both sides of the first memory cell array in a first direction in which the word lines extend are substantially equidistant.

2. The semiconductor memory device according to claim 1, wherein the first plate potential generating circuit is provided at an intersection of the first line and a second line from which memory cells located on both sides of the first memory cell array in a second direction in which the bit lines extend are substantially equidistant.

3. The semiconductor memory device according to claim 1, which further comprises a second memory cell array located adjacent to the first memory cell array in the second direction, and having substantially the same structure as the first memory cell array, and wherein the first plate potential generating circuit is provided between the first and second memory cell arrays.

4. The semiconductor memory device according to claim 3, which further comprises:
a third memory cell array located adjacent to the first memory cell array in the first direction, and having substantially the same structure as the first memory cell array;
a fourth memory cell array located adjacent to the second memory cell array in the first direction, and having substantially the same structure as the first memory cell array; and
a second plate potential generating circuit which mainly applies the predetermined potential to second electrodes of memory cells included in the third and fourth memory cell arrays, and
wherein the first plate potential generating circuit mainly applies the predetermined potential to second electrodes of cells included in the first and second memory cell arrays, and the second plate potential generating circuit is located on a third line from which memory cells on both sides of the third memory cell array in the first direction are substantially equidistant, and is also located between the third and fourth memory cell arrays.

5. The semiconductor memory device according to claim 1, wherein the first plate potential generating circuit comprises a potential generating section which generates the predetermined potential and a potential outputting section which outputs the predetermined potential and is located on the first line.

6. The semiconductor memory device according to claim 1, which further comprises a plate wiring section which includes a plurality of first plate lines provided to extend in a second direction in which the bit lines extend, and connects the second electrodes and the first plate potential generating circuit.

7. The semiconductor memory device according to claim 6, which further comprises a plurality of data lines each of which is provided for a respective predetermined number of bit lines included in the plurality of bit lines and which receive/transmit data from/to the bit lines, and wherein the first plate lines are provided in units of the predetermined number of bit lines.

8. The semiconductor memory device according to claim 6, wherein the plate wiring section includes a plurality of second plate lines provided to extend in the first direction and connecting the plurality of first plate lines.

9. The semiconductor memory device according to claim 8, wherein the first memory cell array includes a plurality of memory cell array portions, which are provided to extend in the second direction, and the second plate lines are provided at ends of the memory cell array portions.

10. A semiconductor memory device comprising:
a first memory cell array in which a plurality of memory cells are arranged in a matrix, the memory cells including memory cell transistors and memory cell capacitors, respectively, the memory cell capacitors including first electrodes and second electrodes, respectively;
a plurality of bit lines connected to the first electrodes by the memory cell transistors;
a plurality of word lines connected to gate electrodes of the memory cell transistors; and
a first plate potential generating circuit which applies a predetermined potential to the second electrodes,
wherein the first plate potential generating circuit is located on a second line from which memory cells located on both sides of the first memory cell array in a second direction in which the bit lines extend are substantially equidistant.

11. The semiconductor memory device according to claim 10, which further comprises a second memory cell array provided adjacent to the first memory cell array in a first direction in which the word lines extend, and having substantially the same structure as the first memory cell array, and wherein the first plate potential generating circuit is located between the first and second memory cell arrays.

12. The semiconductor memory device according to claim 10, wherein the first plate potential generating circuit includes a potential generating section which generates the predetermined potential and a potential outputting section which outputs the predetermined potential and is located on the second line.
